(19) United States
(12) Patent Application Publication
(10) Pub. No.: US 2025/0151202 A1
(43) Pub. Date: May 8, 2025

(54) METHOD AND SYSTEM FOR REMOVING SURFACE INSULATING LAYER OF PRINTED CIRCUIT BOARD OF MONOLITHIC STORAGE DEVICE

(71) Applicant: INSTITUTE OF FORENSIC SCIENCE, MINISTRY OF PUBLIC SECURITY, Beijing (CN)

(72) Inventors: Ning ZHANG, Beijing (CN); Lu ZHAO, Beijing (CN); Zhenwen SUN, Beijing (CN)

(21) Appl. No.: 19/003,596

(22) Filed: Dec. 27, 2024

Related U.S. Application Data
(63) Continuation of application No. PCT/CN2024/079991, filed on Mar. 4, 2024.

(30) Foreign Application Priority Data
May 6, 2023 (CN) 202310507537.6

(51) Int. Cl. H05K 3/00; B23K 26/035; B23K 26/362

(52) U.S. Cl. CPC H05K 3/0026; B23K 26/035; B23K 26/362; H05K 2203/107; H05K 2203/166

(57) ABSTRACT

The present application provides a method and a system for removing a surface insulating layer of a printed circuit board of a monolithic storage device, and relates to the field of electronic data forensics technologies. The method includes: receiving three-dimensional tomographic spectrum data of the printed circuit board sent by an optical coherence tomography device, and determining a circuit structure image of the printed circuit board according to the three-dimensional tomographic spectrum data; determining at least one key pin position according to the circuit structure image, the key pin position being a pin position corresponding to a memory chip in the printed circuit board; and controlling, in accordance with each key pin position, a laser etcher to ablate an insulating layer covering the key pin position.

### CROSS-REFERENCE TO RELATED APPLICATIONS

The present application is a continuation of International Application No. PCT/CN2024/079991, filed on Mar. 4, 2024, which claims priority to Chinese Patent Application No. 202310507537.6, entitled “METHOD AND SYSTEM FOR REMOVING SURFACE INSULATING LAYER OF PRINTED CIRCUIT BOARD OF MONOLITHIC STORAGE DEVICE” and filed with the China National Intellectual Property Administration on May 6, 2023. These applications are hereby incorporated by reference in their entireties.

### TECHNICAL FIELD

The present application relates to the field of electronic data forensics technologies and, in particular, to a method and a system for removing a surface insulating layer of a printed circuit board of a monolithic storage device.

### BACKGROUND

Monolithic storage devices are widely used in various electronic devices and systems due to their advantages such as small size, high performance, high reliability and ease of use. The monolithic storage device may be, for example, a micro-SD card, an integrated USB flash memory card, a multimedia storage card and so on. The monolithic storage device may not function properly due to damage or failure (in most cases, the damage or failure is caused by problems with an interface and/or controller of the monolithic storage device), or may lose critical or sensitive data due to man-induced deletion. In this case, it is necessary to bypass the interface and controller of such storage device and directly access a storage chip (that is, a memory chip) inside the device to read and recover the data.

The monolithic storage device generally adopts an integrated design, and its interface, controller and memory chip are all packaged on a printed circuit board (printed circuit board, PCB) covered, on a surface thereof, with a black and non-transparent insulating layer (usually epoxy resin material). Therefore, when recovering data on a monolithic storage device that is damaged or malfunctioning due to problems with the interface and/or controller, an entire insulating layer of the monolithic storage device is removed at present by manual sanding with sandpaper to expose a structure and a routing direction of a circuit on the printed circuit board, thereby identifying a pin for accessing the memory chip, and then connecting a contact of the pin to a data recovery system through a welding wire, so that the data recovery system can communicate directly with the memory chip without going through the interface and controller of the monolithic storage device.

However, when the insulating layer is removed by manual sanding, the risk of damage to the circuit increases. In addition, when the printed circuit board is exposed to the air for a long time, its copper layer is easily oxidized, which has an adverse effect on the circuit.

### SUMMARY

The present application provides a method and a system for removing a surface insulating layer of a printed circuit board of a monolithic storage device, which is beneficial to reducing the risk of damage to an internal circuit or other components, achieving minimal breakdown to the monolithic storage device, and effectively reducing the difficulty of subsequent welding.

In a first aspect, the present application provides a method for removing a surface insulating layer of a printed circuit board of a monolithic storage device. The method is applied to a control device and may include:
receiving three-dimensional tomographic spectrum data of the printed circuit board sent by an optical coherence tomography device, and determining a circuit structure image of the printed circuit board according to the three-dimensional tomographic spectrum data;
determining at least one key pin position according to the circuit structure image, where the key pin position is a pin position corresponding to a memory chip in the printed circuit board; and
controlling, in accordance with each key pin position, a laser etcher to ablate an insulating layer covering the key pin position.

In a possible implementation, controlling, in accordance with each key pin position, the laser etcher to ablate the insulating layer covering the key pin position includes:
controlling a robotic arm to move to each key pin position in sequence, and when it is detected that the robotic arm reaches any key pin position, controlling, according to etching information, the laser etcher to emit etching laser; where the etching laser is used to pass through a common optical path scanning probe mounted on the robotic arm, to ablate the insulating layer covering the key pin position, and the etching information includes power and spot size of the etching laser.

In a possible implementation, the three-dimensional tomographic spectrum data further includes three-dimensional insulating layer information and three-dimensional pin contact information of the printed circuit board, and before controlling, according to the etching information, the laser etcher to emit the etching laser, the method further includes:
calculating thickness of the insulating layer covering each key pin position according to the three-dimensional insulating layer information, and calculating contact size of each key pin according to the three-dimensional pin contact information;
determining the power of the etching laser at each key pin position according to the thickness of the insulating layer covering each key pin position; and
determining the spot size of the etching laser at each key pin position according to the contact size of each key pin.

In a possible implementation, determining the at least one key pin position according to the circuit structure image includes:
comparing the circuit structure image with a target circuit structure image in a preset database, to determine a definition of each key pin and record each key pin position, where the target circuit structure image is a circuit structure image of a printed circuit board of a target storage device, and a model of the target storage device is the same as a model of the monolithic storage device.

In a second aspect, the present application provides a system for removing a surface insulating layer of a printed circuit board of a monolithic storage device. The system includes an optical coherence tomography device, a control device, a laser etcher, and a common optical path scanning probe;
the optical coherence tomography device is configured to obtain three-dimensional tomographic spectrum data of the printed circuit board;
the control device is configured to: receive the three-dimensional tomographic spectrum data of the printed circuit board sent by the optical coherence tomography device;

determine a circuit structure image of the printed circuit board according to the three-dimensional tomographic spectrum data; determine at least one key pin position according to the circuit structure image, the key pin position being a pin position corresponding to a memory chip in the printed circuit board; and control, in accordance with each key pin position, the laser etcher to ablate an insulating layer covering the key pin position;
the laser etcher is configured to emit etching laser;
the common optical path scanning probe is configured to transmit the etching laser to the key pin position, and the etching laser is used to ablate the insulating layer covering the key pin position.

In a possible implementation, the system further includes a robotic arm, where when being configured to control, in accordance with each key pin position, the laser etcher to ablate the insulating layer covering the key pin position, the control device is specifically configured to:
control the robotic arm to move to each key pin position in sequence, and when it is detected that the robotic arm reaches any key pin position, control, according to etching information, the laser etcher to emit the etching laser; where the etching information includes power and spot size of the etching laser.

In a possible implementation, the three-dimensional tomographic spectrum data further includes three-dimensional insulating layer information and three-dimensional pin contact information of the printed circuit board, and before controlling, according to the etching information, the laser etcher to emit the etching laser, the control device is further configured to:
calculate thickness of the insulating layer covering each key pin position according to the three-dimensional insulating layer information, and calculate contact size of each key pin according to the three-dimensional pin contact information;
determine the power of the etching laser at each key pin position according to the thickness of the insulating layer covering each key pin position; and
determine the spot size of the etching laser at each key pin position according to the contact size of each key pin.

In a possible implementation, when being configured to determine the at least one key pin position according to the circuit structure image, the control device is specifically configured to:
compare the circuit structure image with a target circuit structure image in a preset database, to determine a definition of each key pin and record each key pin position, where the target circuit structure image is a circuit structure image of a printed circuit board of a target storage device, and a model of the target storage device is the same as a model of the monolithic storage device.

In a possible implementation, the common optical path scanning probe is mounted on the robotic arm, and the common optical path scanning probe includes a first collimator, a second collimator, a dichroic mirror, a two-dimensional galvanometer and an objective lens;
the etching laser passes through the second collimator, the dichroic mirror, the two-dimensional galvanometer and the objective lens to ablate the insulating layer covering the key pin position;
the robotic arm drives movement of the common optical path scanning probe, to use the etching laser to ablate the insulating layer covering each key pin position.

In a possible implementation, the optical coherence tomography device includes an optical coherence tomography light source, a coupler, a reference arm, a spectrometer, the first collimator, the dichroic mirror, the two-dimensional galvanometer and the objective lens;
the coupler splits light emitted by the optical coherence tomography light source into reference light and probe light, where the probe light passes through the first collimator, the dichroic mirror, the two-dimensional galvanometer and the objective lens to scan the printed circuit board, and is reflected by a surface of the printed circuit board and then returns to the coupler along an original path to form interference light with the reference light returned by the reference arm; and the coupler outputs the interference light to the spectrometer, and the spectrometer collects the interference light to obtain the three-dimensional tomographic spectrum data; the dichroic mirror is configured to reflect the probe light and allow the etching laser to transmit through.

In a third aspect, the present application provides an apparatus for removing a surface insulating layer of a printed circuit board of a monolithic storage device. The apparatus includes a first determining module, a second determining module, and a control module, where:
the first determining module is configured to receive three-dimensional tomographic spectrum data of the printed circuit board sent by an optical coherence tomography device, and determine a circuit structure image of the printed circuit board according to the three-dimensional tomographic spectrum data;
the second determining module is configured to determine at least one key pin position according to the circuit structure image, where the key pin position is a pin position corresponding to a memory chip in the printed circuit board; and
the control module is configured to control, in accordance with each key pin position, a laser etcher to ablate an insulating layer covering the key pin position.

In a possible implementation, the control module is specifically configured to:
control a robotic arm to move to each key pin position in sequence, and when it is detected that the robotic arm reaches any key pin position, control, according to etching information, the laser etcher to emit etching laser; where the etching laser is used to pass through a common optical path scanning probe mounted on the robotic arm, to ablate the insulating layer covering the key pin position, and the etching information includes power and spot size of the etching laser.

In a possible implementation, the three-dimensional tomographic spectrum data further includes three-dimensional insulating layer information and three-dimensional pin contact information of the printed circuit board, and before controlling, according to the etching information, the laser etcher to emit the etching laser, the apparatus further includes:
a calculating module, configured to: calculate thickness of the insulating layer covering each key pin position according to the three-dimensional insulating layer information, and calculate contact size of each key pin according to the three-dimensional pin contact information;
a third determining module, configured to determine the power of the etching laser at each key pin position according to the thickness of the insulating layer covering each key pin position; and
a fourth determining module, configured to determine the spot size of the etching laser at each key pin position according to the contact size of each key pin.

In a possible implementation, the second determining module is specifically configured to:
compare the circuit structure image with a target circuit structure image in a preset database, to determine a definition of each key pin and record each key pin position, where the target circuit structure image is a circuit structure image of a printed circuit board of a target storage device, and a model of the target storage device is the same as a model of the monolithic storage device.

In a fourth aspect, the present application provides an electronic device, including: a processor and a memory; where the memory stores computer-executable instructions; the processor executes the computer-executable instructions stored in the memory, and is enabled to execute the method for removing the surface insulation layer of the printed circuit board of the monolithic storage device as described in the first aspect or any possible implementation of the first aspect.

In a fifth aspect, the present application provides a computer-readable storage medium, and the computer-readable storage medium stores therein computer-executable instructions which, when executed by a processor, are used to implement the method for removing the surface insulation layer of the printed circuit board of the monolithic storage device as described in the first aspect or any possible implementation of the first aspect.

In a sixth aspect, the present application provides a computer program product, including a computer program, where the computer program, when executed by a processor, implements the method for removing the surface insulating layer of the printed circuit board of the monolithic storage device as described in the first aspect or any possible implementation of the first aspect.

In the embodiment of the present application, a control device receives three-dimensional tomographic spectrum data of a printed circuit board sent by an optical coherence tomography device, determines a circuit structure image of the printed circuit board according to the three-dimensional tomographic spectrum data; determines at least one key pin position according to the circuit structure image, the key pin position being a pin position corresponding to a memory chip in the printed circuit board; and controls, in accordance with each key pin position, a laser etcher to ablate an insulating layer covering the key pin position. The insulating layer covering the pin position corresponding to the memory chip can be automatically, accurately and selectively removed without any manual intervention throughout the process, reducing the risk of damage to an internal circuit or other components, achieving minimal breakdown to the monolithic storage device, effectively reducing the difficulty of subsequent welding, and greatly simplifying the pre-processing process of recovering and extracting electronic data from the monolithic storage device.

### BRIEF DESCRIPTION OF DRAWINGS

FIG. 1 is a schematic diagram of an architecture of a system for removing a surface insulating layer of a printed circuit board of a monolithic storage device provided by an embodiment of the present application;

FIG. 2 is a first schematic diagram of a flow of a method for removing a surface insulating layer of a printed circuit board of a monolithic storage device provided by an embodiment of the present application;

FIG. 3 is a second schematic diagram of a flow of a method for removing a surface insulating layer of a printed circuit board of a monolithic storage device provided by an embodiment of the present application;

FIG. 4 is a schematic diagram of a specific structure of a system for removing a surface insulating layer of a printed circuit board of a monolithic storage device provided by an embodiment of the present application;

FIG. 5 is a schematic diagram of a structure of an apparatus for removing a surface insulating layer of a printed circuit board of a monolithic storage device provided by an embodiment of the present application;

FIG. 6 is a schematic diagram of a structure of an electronic device provided by an embodiment of the present application.

### DESCRIPTION OF EMBODIMENTS

In order to make the purpose, technical solutions and advantages of the present application clearer, the technical solutions in embodiments of the present application will be described clearly and completely in conjunction with the accompanying drawings of the present application. Obviously, the described embodiments are part of the embodiments of the present application, rather than all of the embodiments. Based on the embodiments in the present application, all other embodiments obtained by those of ordinary skill in the art without creative work shall belong to the protection scope of the present application.

The words “first”, “second”, and the like in the embodiments of the present application are used to distinguish the same or similar items with basically the same functions and effects. For example, a first chip and a second chip are merely used to distinguish different chips, and their order is not limited. Those skilled in the art can understand that the words “first”, “second”, and the like are not intended to limit the quantity and execution order, and the words “first”, “second”, and the like are not intended to limit that they are definitely different.

It should be noted that, in the embodiments of the present application, the expression such as “exemplary” or “for example” indicates being used as an example, illustration or description. Any embodiment or design scheme described as “exemplary” or “for example” in the present application should not be construed as preferable or advantageous over other embodiments or design schemes. To be precise, the use of the expression such as “exemplary” or “for example” is intended to present the relevant concepts in a concrete fashion.

It should be understood that although various steps in the flowcharts in the embodiments of the present application are displayed in sequence as indicated by arrows, these steps are not necessarily executed in the order indicated by the arrows. Unless otherwise specified herein, there is no strict order limitation for the execution of these steps and they may be executed in other orders. Moreover, at least part of the steps in the drawings may include at least one sub-step or at least one stage. These sub-steps or stages are not necessarily executed at the same time but may be executed at different times, and their execution order is not necessarily sequential but may be executed alternately or in turn with other steps or at least part of the sub-steps or stages of other steps.

Monolithic storage devices have the advantages of small size, high performance, high reliability, and ease of use. Therefore, the monolithic storage devices are widely used in various electronic devices and systems. The monolithic storage device may be, for example, a micro-SD card, an integrated USB flash memory card, a multimedia storage card and so on.

The monolithic storage device generally adopts an integrated design, and its interface, controller, and internal storage chip (hereinafter referred to as memory chip) are all packaged on a printed circuit board (PCB). Under normal circumstances, the monolithic storage device can communicate with a terminal device through its interface and controller, so that the terminal device can read data stored in the monolithic storage device.

However, the monolithic storage device may not function properly due to damage or failure (in most cases, the damage or failure is caused by problems with an interface and/or controller of the monolithic storage device), or may lose critical or sensitive data due to man- induced deletion. In this case, it is necessary to bypass the interface and controller of such storage device and directly access the memory chip of the storage device to read and recover the data. Data recovery from damaged or malfunctioned monolithic storage devices is a major need in fields such as forensic science and judicial identification.

The printed circuit board of the monolithic storage device is covered, on its surface,

with a black and non-transparent insulating layer (usually epoxy resin material). This insulating layer can be used to protect a copper layer on the printed circuit board from air oxidation to protect a circuit on the printed circuit board, but it may render that it is impossible for a user to view the structure and routing direction of the circuit on the printed circuit board with naked eyes. Therefore, when recovering data on the monolithic storage device that is damaged or malfunctioning due to problems with the interface and/or controller, an entire insulating layer of the monolithic storage device is at present removed by manual sanding with sandpaper, to expose the structure and routing direction of the circuit on the printed circuit board, thereby identifying a pin for accessing the memory chip according to the structure and routing direction of the circuit and determining the definition of the pin, and then connecting a contact of the pin to a data recovery system through a welding wire, so that the data recovery system can communicate directly with the memory chip without going through the interface and controller of the monolithic storage device.

However, removing the insulation layer through manual sanding may cause the problems as follows.
1. The copper layer or other components on the printed circuit board may be damaged, which may adversely affect the integrity and data recovery of the monolithic storage device. The integrity of physical evidence is particularly important in judicial proceedings. Only by ensuring that the physical evidence is intact to the greatest extent, can the reliability and acceptability of the recovered data be effectively ensured.
2. It is difficult to control the sanding position accurately with manual sanding methods, and only the entirety of or majority of the insulating layer can be sanded off, increasing the risk of damage to the circuit. Moreover, when the printed circuit board is exposed to the air for a long time, its copper layer is prone to oxidization, which has an adverse effect on the circuit. In addition, the sanding depth is also difficult to control accurately. The copper layer or components on the printed circuit board may be easily damaged with too deep sanding, and the pins cannot be exposed with too shallow sanding.
3. The sanding process also may generate dust and debris that may interfere with data recovery.
4. The current sanding removal process is time-consuming and laborious, which requires specialized skills and expertise, greatly increasing the workload and work complexity.

Based on the problems mentioned above, an embodiment of the present application provides a method for removing a surface insulating layer of a printed circuit board of a monolithic storage device. In this method, a control device obtains a circuit structure image corresponding to the printed circuit board through an optical coherence tomography (OCT) device, determines a pin position corresponding to a memory chip of the printed circuit board according to the circuit structure image, and then controls a laser etcher to remove an insulating layer covering the pin position. The insulating layer covering the pin position corresponding to the memory chip can be automatically, accurately and selectively removed without any manual intervention throughout the process, reducing the risk of damage to an internal circuit or other components, achieving minimal breakdown to the monolithic storage device, effectively reducing the difficulty of subsequent welding, and greatly simplifying the pre-processing process of recovering and extracting electronic data from the monolithic storage device.

The technical solutions shown in the present application are described in detail below through specific embodiments. It should be noted that the following embodiments may exist alone or in combination with each other, and the same or similar contents will not be described repeatedly in different embodiments.

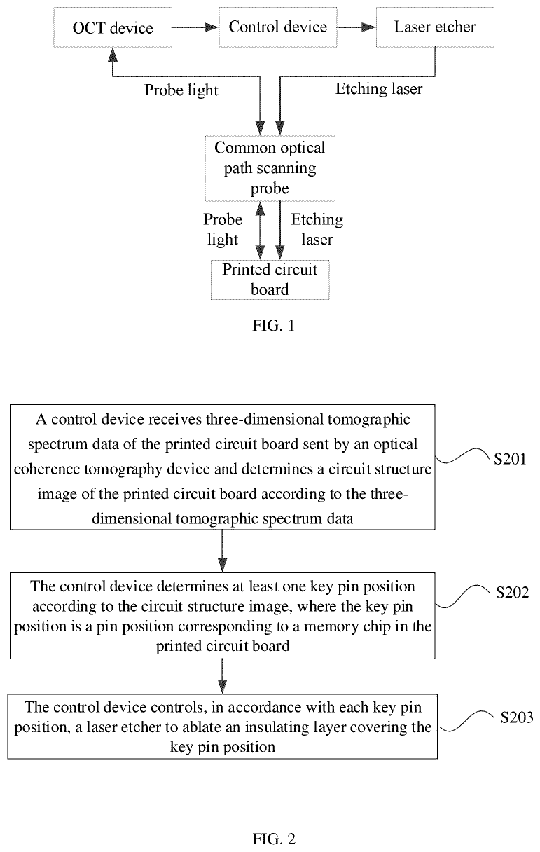

Illustratively, FIG. 1 shows a schematic diagram of an architecture of a system removing a surface insulating layer of a printed circuit board of a monolithic storage device provided by an embodiment of the present application. As shown in FIG. 1, the system may include an optical coherence tomography device (OCT device), a control device, a laser etcher, and a common optical path scanning probe.

The optical coherence tomography device is configured to obtain three-dimensional tomographic spectrum data of the printed circuit board and send the three-dimensional tomographic spectrum data to the control device.

Exemplarily, the optical coherence tomography device scans the printed circuit board through the emitted probe light, to obtain the three-dimensional tomographic spectrum data of the printed circuit board. The optical coherence tomography device includes an optical coherence tomography probe (OCT probe), and the probe light is transmitted to the printed circuit board through the OCT probe. The OCT probe is integrated in the common optical path scanning probe, and therefore the probe light emitted by the optical coherence tomography device can go through the common optical path scanning probe.

In the embodiment of the present application, the printed circuit board refers to a printed circuit board of a monolithic storage device. An interface, a controller and a memory chip of the monolithic storage device are packaged on the printed circuit board, and the printed circuit board is covered with a black and non-transparent insulating layer.

The control device is configured to: receive the three-dimensional tomographic spectrum data of the printed circuit board sent by the optical coherence tomography device, and determine a circuit structure image of the printed circuit board according to the three- dimensional tomographic spectrum data; determine at least one key pin position according to the circuit structure image, the key pin position being a pin position corresponding to a memory chip in the printed circuit board; and control, in accordance with each key pin position, the laser etcher to ablate an insulating layer covering the key pin position.

In the embodiment of the present application, the control device may be a terminal device with a data processing function. Exemplarily, the control device may be a personal computer (PC).

The laser etcher is configured to emit etching laser, and the etching laser reaches the key pin position through an optical path of the common optical path scanning probe. The common optical path scanning probe is configured to transmit the etching laser to the key pin position, and the etching laser is used to ablate the insulating layer covering the key pin position.

The system in the embodiment of the present application controls, through the control device, the laser etcher to emit the etching laser to ablate the insulating layer covering the key pin position, to vaporize the insulating layer, thereby avoiding the problem in related arts that dust and debris generated during manual sanding would affect subsequent data recovery. Furthermore, the system can automatically remove the surface insulating layer of the printed circuit board. Compared with the manual sanding, the system does not require manual intervention or removal of the entire insulating layer, which effectively improves the efficiency of insulating layer removal, thereby improving the data recovery efficiency of the monolithic storage device that is damaged or malfunctioning due to the problems with the interface and/or controller.

FIG. 2 shows a first schematic diagram of a flow of a method for removing a surface insulating layer of a printed circuit board of a monolithic storage device provided by an embodiment of the present application. As shown in FIG. 2, the method may include the following steps.

S201: a control device receives three-dimensional tomographic spectrum data of the printed circuit board sent by an optical coherence tomography device and determines a circuit structure image of the printed circuit board according to the three-dimensional tomographic spectrum data.

The circuit structure image may include a structure and routing direction of a circuit on the printed circuit board of the monolithic storage device.

In a possible implementation, the optical coherence tomography device scans the printed circuit board through emitted probe light to obtain the three-dimensional tomographic spectrum data of the printed circuit board, and sends the three-dimensional tomographic spectrum data to the control device, which processes the three-dimensional tomographic spectrum data to obtain the circuit structure image of the printed circuit board.

Exemplarily, the control device may include a data processing module, which is configured to convert the three-dimensional tomographic spectrum data of the printed circuit board received from the optical coherence tomography device into the circuit structure image of the printed circuit board.

S202: the control device determines at least one key pin position according to the circuit structure image, where the key pin position is a pin position corresponding to a memory chip in the printed circuit board.

In order to reduce the damage to the printed circuit board to achieve lossless data recovery, in the embodiment of the present application, instead of the entire insulating layer covering the printed circuit board being removed, only the insulating layer covering the pin position corresponding to the memory chip in the printed circuit board may be removed. Therefore, the control device needs to first determine the pin position corresponding to the memory chip in the circuit structure image of the printed circuit board, that is, the key pin position, for subsequent removal of the insulating layer covering the key pin position.

The key pin position may be a three-dimensional space coordinate corresponding to the key pin.

In a possible implementation, the control device determines a definition of each pin in the circuit structure image of the printed circuit board to determine which pins are key pins, thereby determining and recording the positions of the key pins.

S203: the control device controls, in accordance with each key pin position, a laser etcher to ablate an insulating layer covering the key pin position.

It can be understood that there are a plurality of pins, that is, key pins, corresponding to the memory chip, and the memory chip is connected to other components in the printed circuit board through these pins to form the circuit structure of the printed circuit board.

In a possible implementation, the control device controls the laser etcher to ablate the insulating layer covering the key pins one by one. In this way, the laser etcher is used to ablate the insulating layer for vaporization, thereby avoiding the disadvantages of related arts, that is, dust and debris generated during the sanding process will not interfere with subsequent data recovery.

In an embodiment of the present application, three-dimensional tomographic spectrum data of a printed circuit board sent by an optical coherence tomography device is received, a circuit structure image of the printed circuit board is determined according to the three-dimensional tomographic spectrum data; at least one key pin position is determined according to the circuit structure image, the key pin position being a pin position corresponding to a memory chip in the printed circuit board; and a laser etcher is controlled in accordance with each key pin position to ablate an insulating layer covering the key pin position. The insulating layer covering the pin position corresponding to the memory chip can be automatically, accurately and selectively removed without any manual intervention throughout the process, reducing the risk of damage to an internal circuit or other components, achieving minimal breakdown to the monolithic storage device, effectively reducing the difficulty of subsequent welding, and greatly simplifying the pre-processing process of recovering and extracting electronic data from the monolithic storage device.

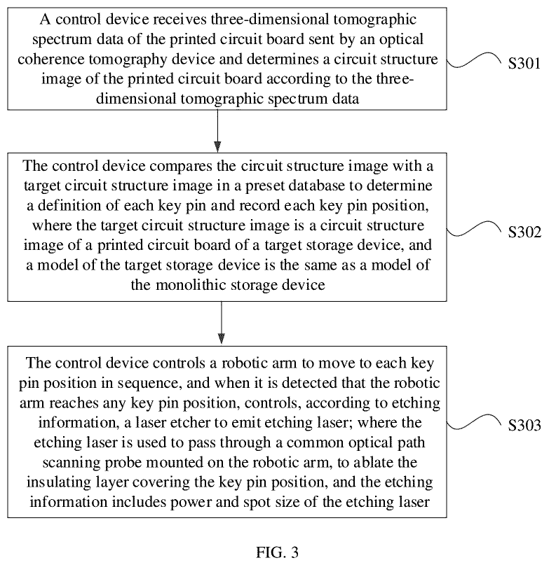

On the basis of the above embodiments, in order to more clearly describe the technical solution of the present application, illustratively, FIG. 3 shows a second schematic diagram of a flow of a method for removing a surface insulating layer of a printed circuit board of a monolithic storage device provided by an embodiment of the present application. As shown in FIG. 3, the method may include the following steps.

S301: a control device receives three-dimensional tomographic spectrum data of the printed circuit board sent by an optical coherence tomography device, and determines a circuit structure image of the printed circuit board according to the three-dimensional tomographic spectrum data.

This step is similar or identical to the above step S201 and will not be repeated here.

S302: the control device compares the circuit structure image with a target circuit structure image in a preset database, to determine a definition of each key pin and record each key pin position, where the target circuit structure image is a circuit structure image of a printed circuit board of a target storage device, and a model of the target storage device is the same as a model of the monolithic storage device.

In the embodiment of the present application, the circuit structure image determined by the control device according to the three-dimensional tomographic spectrum data may carry the model of the monolithic storage device to which the printed circuit board corresponding to the circuit structure image belongs.

In a possible implementation, the control device is preset with the preset database, which includes circuit structure images corresponding to printed circuit boards of different models of monolithic storage devices. Each circuit structure image in the preset database carries its own circuit information, and the circuit information includes a pin definition. In other words, the pin definition of each circuit structure image in the preset database is known. After the control device determines the circuit structure image of the printed circuit board according to the three-dimensional tomographic spectrum data, it can compare the circuit structure image of the printed circuit board with the target circuit structure image in the preset database to identify which pins in the circuit structure image of the printed circuit board are the pins of the memory chip, determine the definition of each key pin, and record each key pin position.

In the embodiment of the present application, the three-dimensional tomographic spectrum data of the printed circuit board sent by the optical coherence tomography device may be three-dimensional tomographic spectrum data of the entirety of the printed circuit board or three-dimensional tomographic spectrum data of a partial area of the printed circuit board. When the optical coherence tomography device sends the three-dimensional tomographic spectrum data of the partial area of the printed circuit board to the control device, the control device determines a circuit structure image (hereinafter referred to as a sub-circuit structure image) corresponding to the partial area of the printed circuit board according to the three-dimensional tomographic spectrum data of the partial area of the printed circuit board.

In a possible implementation, if the sub-circuit structure image happens to include each key pin position, the control device can determine the definition of each key pin and record each key pin position when comparing the sub-circuit structure image with the target circuit structure image; if the sub-circuit structure image does not include each key pin position or only includes some of the key pin positions, the control device can restore the circuit structure image corresponding to the entire printed circuit board based on a subgraph-to-whole-graph registration algorithm, and compare the circuit structure image with the target circuit structure image to identify which pins in the circuit structure image corresponding to the printed circuit board are the pins of the memory chip, determine the definition of each key pin and record each key pin position.

In the embodiment of the present application, the control device determines each key pin position by comparing the circuit structure image with the target circuit structure image, so that the insulating layer covering each key pin position can be subsequently removed in a targeted manner.

S303: the control device controls a robotic arm to move to each key pin position in sequence, and when it is detected that the robotic arm reaches any key pin position, controls, according to etching information, a laser etcher to emit etching laser; where the etching laser is used to pass through a common optical path scanning probe mounted on the robotic arm, to ablate the insulating layer covering the key pin position, and the etching information includes power and spot size of the etching laser.

Exemplarily, after determining each key pin position, the control device can control the robotic arm to move from an initial position to a first key pin position. The initial position can be set according to the actual scenario, which will not be specifically limited in the embodiment of the present application.

When detecting that the robotic arm has moved to the first key pin position, the control device adjusts the power and the spot size of the etching laser of the laser etcher for the first key pin position, and sends an emission instruction to a laser controller. The emission instruction carries the etching information adjusted by the control device for the first key pin position. The emission instruction is used to instruct the laser etcher to emit the etching laser according to the etching information. The etching laser ablates the insulating layer covering the first key pin position through the common optical path scanning probe mounted on the robotic arm. The power and the spot size of the etching laser meet the power and spot size of the etching laser adjusted by the control device for the first key pin position.

It should be noted that the etching laser emitted by the laser etcher is a high-energy pulse laser, the emission stops automatically after one-shot emission, and the emission of the etching laser is not triggered until the laser etcher receives the emission instruction next time.

When the robotic arm reaches the first key pin position, the robotic arm can pause for a period of time to ensure that the etching laser emission is completed, which prevents the movement of the robotic arm from interfering with the ablation process of the etching laser. In practical applications, since the laser etcher completes the emission of the etching laser almost instantly after receiving the emission instruction, the period of time when the robotic arm is paused can be very short. This period of time can also be set according to the specific scenario, which will not be limited in the embodiments of the present application.

Afterwards, the robotic arm continues to move toward a second key pin position. Similarly, when the control device detects that the robotic arm has moved to the second key pin position, the control device adjusts the power and the spot size of the etching laser of the laser etcher for the second key pin position, and sends an emission instruction to the laser controller. The emission instruction carries etching information adjusted by the control device for the second key pin position, and the emission instruction is used to instruct the laser etcher to emit the etching laser according to the etching information. The etching laser ablates an insulating layer covering the second key pin position through the common optical path scanning probe mounted on the robotic arm. The power and spot size of the etching laser meet the power and spot size of the etching laser adjusted by the control device for the second key pin position. Similarly, when the robotic arm reaches the second key pin position, the robotic arm pauses for a period of time as well to ensure that the etching laser emission is completed, which prevents the movement of the robotic arm from interfering with the ablation process of the etching laser.

The above steps are repeated until the robotic arm moves to a last key pin position, and the insulating layer covering all key pin positions is removed by the etching laser by means of ablation. Afterwards, the control device can control the robotic arm to return to the initial position.

In an implementation, the control device can also adjust and set the power and spot size of the etching laser corresponding to each key pin position before the robotic arm moves from the initial position. When the robotic arm moves to any key pin position, the control device controls the laser etcher to emit the etching laser, and the etching laser meets the power and spot size of the etching laser corresponding to the key pin position. The embodiment of the present application does not specifically limit whether the control device sets the power and spot size of the etching laser before or after the robotic arm moves from the initial position.

It can be understood that the first and the second in the first key pin position and the second key pin position as described above do not refer to an order of a specific key pin position, as long as the robotic arm can move to each key pin position in sequence along a moving route without repeatedly going through the same key pin position.

In the embodiment of the present application, from the perspective of ensuring the integrity of physical evidence to the greatest extent, only the insulating layer covering the key pin positions is removed. The control device controls the robotic arm to move to the respective key pin positions in sequence, and at the respective key pin positions, controls, according to the etching information of the respective key pin positions, the laser etcher to emit etching laser, and accurately removes the insulating layer covering the respective key pin positions through the etching laser, to achieve minimal breakdown to the monolithic storage device on the basis of exposing contacts of the key pins.

In a possible implementation, the three-dimensional tomographic spectrum data also includes three-dimensional insulating layer information and three-dimensional pin contact information of the printed circuit board. Before the above-mentioned step of controlling, according to the etching information, the laser etcher to emit the etching laser, the method may further include:
the control device calculating thickness of the insulating layer covering each key pin position according to the three-dimensional insulating layer information, and calculating contact size of each key pin according to the three-dimensional pin contact information; determining the power of the etching laser at each key pin position according to the thickness of the insulating layer covering each key pin position; and determining the spot size of the etching laser at each key pin position according to the contact size of each key pin.

The three-dimensional insulating layer information may be three-dimensional spatial coordinates of the insulating layer, and the three-dimensional pin contact information may be three-dimensional spatial coordinates of the pin contact.

In the embodiment of the present application, the thicker the insulating layer covering the key pin position, the greater the power of the etching laser for removing the insulating layer; the spot size of the etching laser is similar to or the same as the contact size of the key pin, so that the etching laser can remove the insulating layer covering the key pin position, to enable the contact of the key pin to be just exposed, thereby avoiding the situation where the contact of the key pin is incompletely exposed or excessively ablated.

In the embodiment of the present application, after the insulating layer covering each key pin position is removed, the preliminary preparations for data recovery of the monolithic storage device are completed. Furthermore, the exposed contacts at the key pin positions are connected to the data recovery system through wires, so that the data recovery system can directly communicate with the memory chip, thereby realizing data recovery and extraction of the monolithic storage device.

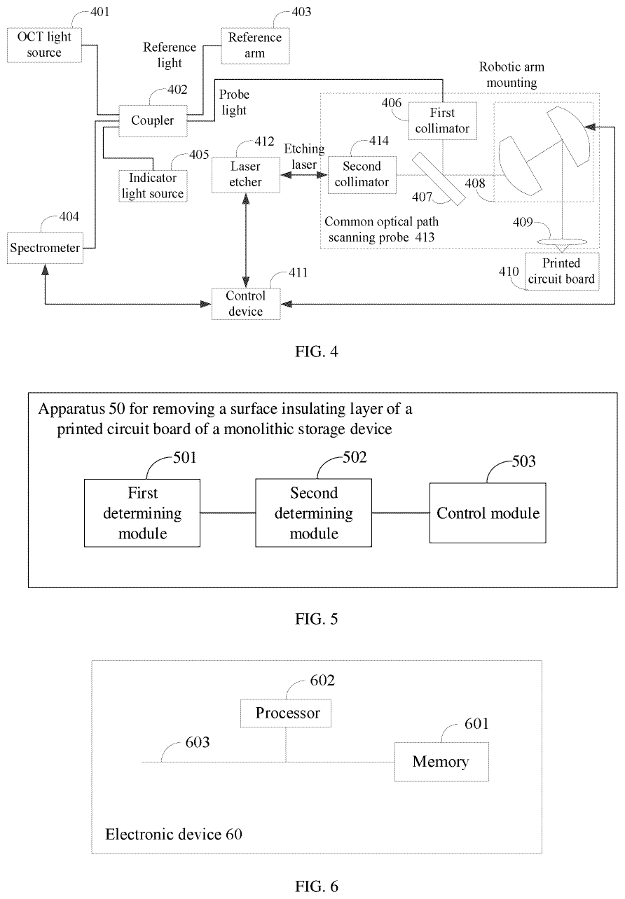

FIG. 4 is a schematic diagram of a specific structure of a system for removing a surface insulating layer of a printed circuit board of a monolithic storage device provided by an embodiment of the present application. As shown in FIG. 4, the system includes an optical coherence tomography device, a control device 411, a laser etcher 412, a common optical path scanning probe 413 and a robotic arm.

The optical coherence tomography device includes an optical coherence tomography light source (OCT light source) 401, a coupler 402, a reference arm 403, a spectrometer 404, a first collimator 406, a dichroic mirror 407, a two-dimensional galvanometer 408 and an objective lens 409.

In the embodiment of the present application, the coupler 402 splits light emitted by the OCT light source 401 into reference light and probe light.

The reference light returns to the coupler 402 after going through the reference arm 403, where the reference arm 403 may include, for example, a third collimator and a plane mirror. Exemplarily, the reference light passes through the third collimator to irradiate onto the plane mirror and then returns to the coupler 402.

The probe light passes through the first collimator 406 to become collimated probe light in a vertical direction; the probe light in the vertical direction is irradiated to the dichroic mirror 407 and reflected to the two-dimensional galvanometer 408 by the dichroic mirror 407; the probe light is irradiated to the objective lens 409 after its path is changed by the two-dimensional galvanometer 408, and irradiated to the surface of the printed circuit board 410 after being focused by the objective lens 409. The probe light returns to the coupler 402 along the original path after being reflected by the surface of the printed circuit board 410, to form interference light with the reference light returned by the reference arm 403. The coupler 402 outputs the interference light to the spectrometer 404, and the spectrometer 404 collects the interference light to obtain three-dimensional tomographic spectrum data. The dichroic mirror 407 is used to reflect the probe light and allow the etching laser to transmit through.

The spectrometer 404 sends the collected three-dimensional tomographic spectrum data to the control device 411. The control device 411 can execute the steps of the method embodiments shown in FIG. 2 or FIG. 3, and the implementation principles and beneficial effects of executing the steps of the method embodiments by the control device 411 are similar to those of the method embodiments shown in FIG. 2 or FIG. 3 and will not be repeated here.

The control device 411 controls the robotic arm to move to each key pin position, where the movement of the robotic arm drives the common optical path scanning probe 413 mounted on the robotic arm to move. The control device 411 controls the laser etcher 412 to emit etching laser, and the etching laser passes through the common optical path scanning probe 413 to ablate the insulating layer covering each key pin position.

The common optical path scanning probe 413 may include a second collimator 414, the dichroic mirror 407 and an OCT probe, where the OCT probe includes a first collimator 406, the two-dimensional galvanometer 408 and the objective lens 409.

Specifically, the etching laser passes through the second collimator 414, the dichroic mirror 407, the two-dimensional galvanometer 408 and the objective lens 409 in the common optical path scanning probe 413 to ablate the insulating layer covering the key pin position.

In the embodiment of the present application, the etching laser and the probe light share a common optical path between the dichroic mirror 407 and the surface of the printed circuit board 410.

After the laser etcher 412 emits the etching laser, the etching laser passes through the second collimator 414 to become collimated etching laser in a horizontal direction. The etching laser in the horizontal direction transmits through the dichroic mirror 407, the two-dimensional galvanometer 408 and then the objective lens 409 to ablate the insulating layer at the key pin position of the printed circuit board 410.

In the embodiment of the present application, the control device 411 can control the swing of the two-dimensional galvanometer 408 by sending different voltage signals to the two-dimensional galvanometer 408, to change a position of the probe light passing through the two-dimensional galvanometer 408, thereby achieving adjustment to a scanning position of the printed circuit board 410, and realizing regional scanning.

When scanning the printed circuit board, an OCT scanning area can be determined first. A light spot emitted by an indicator light source 405 indicates size of a scanning range. The OCT scanning area can be determined based on the size of the scanning range of the indicator light source 405. Exemplarily, if the scanning range is larger than the size of the printed circuit board, the printed circuit board may be located within the scanning range, and the OCT scanning area is the entire printed circuit board; if the scanning range is smaller than the size of the printed circuit board, the OCT scanning area is the area of the printed circuit board within the scanning range.

The system for removing the surface insulation layer of the printed circuit board of the monolithic storage device in the embodiment of the present application obtains three-dimensional tomographic spectrum data through an OCT device and sends same to a control device, so that the control device can accurately locate the key pin position based on the three-dimensional tomographic spectrum data, and control, based on the key pin position, a robotic arm to drive a common optical path scanning probe to move to the key pin position, and control, according to etching information, a laser etcher to emit etching laser to ablate an insulation layer covering the key pin position. The control device accurately locates a corresponding pin position of the memory chip in the printed circuit board of the monolithic storage device based on the three-dimensional tomographic spectrum data, which can avoid the problems of printed circuit board damage, copper layer oxidation, and so on caused by removing the entirety of or majority of the insulating layer due to uncertainty of the key pin position in the related arts, and can reduce the risk of damage to the internal circuit or other components of the printed circuit board, thereby achieving minimal breakdown to the printed circuit board. Moreover, the system controls, through the control device, the laser etcher to emit the etching laser to ablate the insulating layer covering the key pin position so that the insulating layer is vaporized, which avoids the problem of dust and debris generated during manual sanding affecting subsequent data recovery. Furthermore, the system can automatically remove the surface insulating layer of the printed circuit board. Compared with manual sanding, the system does not require manual intervention or removal of the entire insulating layer, which effectively improves the efficiency of insulating layer removal, thereby improving the data recovery efficiency of the monolithic storage device that is damaged or malfunctioning due to the problems with the interface and/or controller.

FIG. 5 is a schematic diagram of a structure of an apparatus for removing a surface insulating layer of a printed circuit board of a monolithic storage device provided by an embodiment of the present application. As shown in FIG. 5, the apparatus 50 for removing the surface insulating layer of the printed circuit board of the monolithic storage device includes: a first determining module 501, a second determining module 502, and a control module 503, where:
the first determining module 501 is configured to: receive three-dimensional tomographic spectrum data of the printed circuit board sent by an optical coherence tomography device, and determine a circuit structure image of the printed circuit board according to the three-dimensional tomographic spectrum data;
the second determining module 502 is configured to determine at least one key pin position according to the circuit structure image, the key pin position being a pin position corresponding to a memory chip in the printed circuit board; and
the control module 503 is configured to control, in accordance with each key pin position, a laser etcher to ablate an insulating layer covering the key pin position.

In a possible implementation, the control module 503 is specifically configured to:
control a robotic arm to move to each key pin position in sequence, and when it is detected that the robotic arm reaches any key pin position, control, according to etching information, the laser etcher to emit etching laser; where the etching laser is used to pass through a common optical path scanning probe mounted on the robotic arm, to ablate the insulating layer covering the key pin position, and the etching information includes power and spot size of the etching laser.

In a possible implementation, the three-dimensional tomographic spectrum data further includes three-dimensional insulating layer information and three-dimensional pin contact information of the printed circuit board, and before controlling, according to the etching information, the laser etcher to emit the etching laser, the apparatus further includes:
a calculating module, configured to: calculate thickness of the insulating layer covering each key pin position according to the three-dimensional insulating layer information, and calculate contact size of each key pin according to the three-dimensional pin contact information;
a third determining module, configured to determine the power of the etching laser at each key pin position according to the thickness of the insulating layer covering each key pin position; and
a fourth determining module, configured to determine the spot size of the etching laser at each key pin position according to the contact size of each key pin.

In a possible implementation, the second determining module 502 is specifically configured to:
compare the circuit structure image with a target circuit structure image in a preset database, determine a definition of each key pin, and record each key pin position, where the target circuit structure image is a circuit structure image of a printed circuit board of a target storage device, and a model of the target storage device is the same as a model of the monolithic storage device.

The apparatus 50 for removing the surface insulating layer of the printed circuit board of the monolithic storage device provided by the embodiment of the present application can implement the technical solution shown in the foregoing embodiment of the method for removing the surface insulating layer of the printed circuit board of the monolithic storage device; and implementation principles and beneficial effects of implementing the technical solution by the apparatus 50 are similar to the foregoing embodiment of the method for removing the surface insulating layer of the printed circuit board of the monolithic storage device, which will not be repeated here.

FIG. 6 is a schematic diagram of a structure of an electronic device provided by an embodiment of the present application. As shown in FIG. 6, the electronic device 60 in this embodiment may include: a memory 601 and a processor 602.

The memory 601 is configured to store computer-executable instructions; and
the processor 602 is configured to execute the computer-executable instructions stored in the memory to implement the various steps executed in the method for removing a surface insulating layer of a printed circuit board of a monolithic storage device in the embodiments described above. For details, please refer to the relevant descriptions in the aforementioned method embodiments.

In an implementation, the memory 601 may be standalone or integrated with the processor 602.

When the memory 601 is in a standalone configuration, the electronic device 60 further includes a bus 603 configured for connecting the memory 601 and the processor 602.

An embodiment of the present application also provides a computer-readable storage medium. The computer-readable storage medium stores therein computer-executable instructions which, when executed by a processor, implements the method for removing a surface insulating layer of a printed circuit board of a monolithic storage device executed by the electronic device mentioned above.

An embodiment of the present application further provides a computer program product, which includes a computer program. When the computer program is executed by a processor, it is used to execute the technical solution of the method for removing a surface insulating layer of a printed circuit board of a monolithic storage device in the embodiments mentioned above.

The computer-readable storage medium can be implemented by any type of volatile or non-volatile memory device or a combination thereof, such as static random-access memory (SRAM), electrically erasable programmable read only memory (EEPROM), erasable programmable read only memory (EPROM), programmable read only memory (PROM), read only memory (ROM), magnetic memory, flash memory, magnetic disk or optical disk. The readable storage medium can be any available medium that can be accessed by a general purpose or special purpose computer.

Other implementation solutions of the present application will be apparent to those skilled in the art after considering the specification and practicing the invention disclosed herein. The present application is intended to cover any modifications, uses or adaptive changes of the present application, which follow the general principles of the present application and include common knowledge or customary technical means in the technical field that are not disclosed in the present application. It is intended that the specification and embodiments be merely considered as exemplary, with a true scope and spirit of the present application being indicated by the following claims.

It should be understood that the present application is not limited to the exact construction that has been described above and shown in the accompanying drawings and that various modifications and changes may be made without departing from the scope thereof. The scope of the present application is limited only by the attached claims.

What is claimed is:

1. A method for removing a surface insulating layer of a printed circuit board of a monolithic storage device, wherein the method is applied to a control device and comprises:
receiving three-dimensional tomographic spectrum data of the printed circuit board sent by an optical coherence tomography device, and determining a circuit structure image of the printed circuit board according to the three-dimensional tomographic spectrum data;
determining at least one key pin position according to the circuit structure image, wherein the key pin position is a pin position corresponding to a memory chip in the printed circuit board; and
controlling, in accordance with each key pin position of the at least one key pin position, a laser etcher to ablate an insulating layer covering the key pin position.

2. The method according to claim 1, wherein controlling, in accordance with each key pin position of the at least one key pin position, the laser etcher to ablate the insulating layer covering the key pin position comprises:
controlling a robotic arm to move to each key pin position of the at least one key pin position in sequence, and controlling, according to etching information, the laser etcher to emit etching laser when it is detected that the robotic arm reaches any key pin position; wherein the etching laser is used to pass through a common optical path scanning probe mounted on the robotic arm, to ablate the insulating layer covering the key pin position, and the etching information comprises power and spot size of the etching laser.

3. The method according to claim 2, wherein the three-dimensional tomographic spectrum data further comprises three-dimensional insulating layer information and three-dimensional pin contact information of the printed circuit board, and before controlling, according to the etching information, the laser etcher to emit the etching laser, the method further comprises:
calculating thickness of the insulating layer covering each key pin position of the at least one key pin position according to the three-dimensional insulating layer information, and calculating contact size of each key pin according to the three-dimensional pin contact information;
determining the power of the etching laser at each key pin position of the at least one key pin position according to the thickness of the insulating layer covering each key pin position of the at least one key pin position;
determining the spot size of the etching laser at each key pin position of the at least one key pin position according to the contact size of each key pin.

4. The method according to claim 1, wherein determining the at least one key pin position according to the circuit structure image comprises:
comparing the circuit structure image with a target circuit structure image in a preset database, to determine a definition of each key pin and record each key pin position of the at least one key pin position, wherein the target circuit structure image is a circuit structure image of a printed circuit board of a target storage device, and a model of the target storage device is the same as a model of the monolithic storage device.

5. A system for removing a surface insulating layer of a printed circuit board of a monolithic storage device, wherein the system comprises an optical coherence tomography device, a control device, a laser etcher, and a common optical path scanning probe;
the optical coherence tomography device is configured to obtain three-dimensional tomographic spectrum data of the printed circuit board;
the control device is configured to: receive the three-dimensional tomographic spectrum data of the printed circuit board sent by the optical coherence tomography device; determine a circuit structure image of the printed circuit board according to the three-dimensional tomographic spectrum data; determine at least one key pin position according to the circuit structure image, the key pin position being a pin position corresponding to a memory chip in the printed circuit board; and control, in accordance with each key pin position of the at least one key pin position, the laser etcher to ablate an insulating layer covering the key pin position;
the laser etcher is configured to emit etching laser;
the common optical path scanning probe is configured to transmit the etching laser to the key pin position, and the etching laser is used to ablate the insulating layer covering the key pin position.

6. The system according to claim 5, further comprising: a robotic arm, wherein when being configured to control, in accordance with each key pin position of the at least one key pin position, the laser etcher to ablate the insulating layer covering the key pin position, the control device is specifically configured to:
control the robotic arm to move to each key pin position of the at least one key pin position in sequence, and when it is detected that the robotic arm reaches any key pin position, control, according to etching information, the laser etcher to emit the etching laser; wherein the etching information comprises power and spot size of the etching laser.

7. The system according to claim 6, wherein the three-dimensional tomographic spectrum data further comprises three-dimensional insulating layer information and three-dimensional pin contact information of the printed circuit board, and before controlling, according to the etching information, the laser etcher to emit the etching laser, the control device is further configured to:
calculate thickness of the insulating layer covering each key pin position of the at least one key pin position according to the three-dimensional insulating layer information, and calculate contact size of each key pin according to the three-dimensional pin contact information;
determine the power of the etching laser at each key pin position of the at least one key pin position according to the thickness of the insulating layer covering each key pin position of the at least one key pin position; and
determine the spot size of the etching laser at each key pin position of the at least one key pin position according to the contact size of each key pin.

8. The system according to claim 5, wherein when being configured to determine the at least one key pin position according to the circuit structure image, the control device is specifically configured to:
compare the circuit structure image with a target circuit structure image in a preset database, to determine a definition of each key pin and record each key pin position of the at least one key pin position, wherein the target circuit structure image is a circuit structure image of a printed circuit board of a target storage device, and a model of the target storage device is the same as a model of the monolithic storage device.

9. The system according to claim 8, wherein the common optical path scanning probe is mounted on a robotic arm, and the common optical path scanning probe comprises a first collimator, a second collimator, a dichroic mirror, a two-dimensional galvanometer and an objective lens;
the etching laser passes through the second collimator, the dichroic mirror, the two-dimensional galvanometer and the objective lens to ablate the insulating layer covering the key pin position;
the robotic arm drives movement of the common optical path scanning probe, to use the etching laser to ablate the insulating layer covering each key pin position of the at least one key pin position.

10. The system according to claim 9, wherein the optical coherence tomography device comprises an optical coherence tomography light source, a coupler, a reference arm, a spectrometer, the first collimator, the dichroic mirror, the two-dimensional galvanometer and the objective lens;
the coupler splits light emitted by the optical coherence tomography light source into reference light and probe light, wherein the probe light passes through the first collimator, the dichroic mirror, the two-dimensional galvanometer and the objective lens to scan the printed circuit board, and is reflected by a surface of the printed circuit board and then returns to the coupler along an original path to form interference light with the reference light returned by the reference arm; and the coupler outputs the interference light to the spectrometer, and the spectrometer collects the interference light to obtain the three-dimensional tomographic spectrum data; wherein the dichroic mirror is configured to reflect the probe light and allow the etching laser to transmit through.

11. An electronic device, comprising: a processor, and a memory communicatively connected to the processor;
wherein the memory stores computer-executable instructions; and
the processor executes the computer-executable instructions stored in the memory to:
receive three-dimensional tomographic spectrum data of a printed circuit board sent by an optical coherence tomography device, and determine a circuit structure image of the printed circuit board according to the three-dimensional tomographic spectrum data;
determine at least one key pin position according to the circuit structure image, wherein the key pin position is a pin position corresponding to a memory chip in the printed circuit board; and
control, in accordance with each key pin position of the at least one key pin position, a laser etcher to ablate an insulating layer covering the key pin position.

12. The electronic device according to claim 11, wherein the processor is further enabled to:
control a robotic arm to move to each key pin position of the at least one key pin position in sequence, and control, according to etching information, the laser etcher to emit etching laser when it is detected that the robotic arm reaches any key pin position; wherein the etching laser is used to pass through a common optical path scanning probe mounted on the robotic arm, to ablate the insulating layer covering the key pin position, and the etching information comprises power and spot size of the etching laser.

13. The electronic device according to claim 12, wherein the three-dimensional tomographic spectrum data further comprises three-dimensional insulating layer information and three-dimensional pin contact information of the printed circuit board, and the processor is further enabled to:
calculate thickness of the insulating layer covering each key pin position of the at least one key pin position according to the three-dimensional insulating layer information, and calculate contact size of each key pin according to the three-dimensional pin contact information;
determine the power of the etching laser at each key pin position of the at least one key pin position according to the thickness of the insulating layer covering each key pin position of the at least one key pin position;
determine the spot size of the etching laser at each key pin position of the at least one key pin position according to the contact size of each key pin.

14. The electronic device according to claim 11, wherein the processor is further enabled to:
compare the circuit structure image with a target circuit structure image in a preset database, to determine a definition of each key pin and record each key pin position of the at least one key pin position, wherein the target circuit structure image is a circuit structure image of a printed circuit board of a target storage device, and a model of the target storage device is the same as a model of a monolithic storage device.

15. A non-volatile computer-readable storage medium storing computer-executable instructions therein, wherein the computer-executable instructions, when executed by a processor, are used to implement the method according to claim 1.

16. The non-volatile computer-readable storage medium according to claim 15, wherein the computer-executable instructions further enable the processor to:
control a robotic arm to move to each key pin position of the at least one key pin position in sequence, and control, according to etching information, the laser etcher to emit etching laser when it is detected that the robotic arm reaches any key pin position; wherein the etching laser is used to pass through a common optical path scanning probe mounted on the robotic arm, to ablate the insulating layer covering the key pin position, and the etching information comprises power and spot size of the etching laser.

17. The non-volatile computer-readable storage medium according to claim 16, wherein the three-dimensional tomographic spectrum data further comprises three-dimensional insulating layer information and three-dimensional pin contact information of the printed circuit board, and the computer-executable instructions further enable the processor to:
calculate thickness of the insulating layer covering each key pin position of the at least one key pin position according to the three-dimensional insulating layer information, and calculate contact size of each key pin according to the three-dimensional pin contact information;
determine the power of the etching laser at each key pin position of the at least one key pin position according to the thickness of the insulating layer covering each key pin position of the at least one key pin position;
determine the spot size of the etching laser at each key pin position of the at least one key pin position according to the contact size of each key pin.

18. The non-volatile computer-readable storage medium according to claim 15, wherein the computer-executable instructions further enable the processor to:
compare the circuit structure image with a target circuit structure image in a preset database, to determine a definition of each key pin and record each key pin position of the at least one key pin position, wherein the target circuit structure image is a circuit structure image of a printed circuit board of a target storage device, and a model of the target storage device is the same as a model of the monolithic storage device.
